(19) United States
(12) Patent Application Publication
(10) Pub. No.: US 2008/0284472 A1
(43) Pub. Date: Nov. 20, 2008

(54) APPARATUS FOR ADJUSTING BANDWIDTH AND CENTRAL FREQUENCY OF OSCILLATING SIGNAL GENERATED FROM CHAOTIC SIGNAL AND METHOD FOR GENERATING SIGNAL THEREOF

(75) Inventors: Sang-min HAN, Hwanseong-si (KR); Alexander S. Dmitriev, Moscow (RU); Jin-Soo Park, Yongin-si (KR); Hyoung-Woon Park, Seongnam-si (KR)

Correspondence Address: SUGHRUE MION, PLLC, 2100 PENNSYLVANIA AVENUE, N.W., SUITE 800, WASHINGTON, DC, 20037, US

(73) Assignees: Samsung Electronics Co., Ltd., Suwon-si (KR); INSTITUTE OF RADIO ENGINEERING AND ELECTRONICS OF RAS, Moscow (RU)

(21) Appl. No.: 11/876,802

(22) Filed: Oct. 23, 2007

(30) Foreign Application Priority Data
May 16, 2007 (KR) 10-2007-0047696

(51) Int. Cl. H03B 28/00

(52) U.S. Cl. 327/113

(57) ABSTRACT

A communication apparatus and a method for generating a signal thereof are provided. The communication apparatus adjusts a bandwidth or central frequency of an oscillating signal which is generated from a chaotic signal to be used in the modulation, or adjusts both the bandwidth and the central frequency. Accordingly, it is possible to transform the oscillating signal generated from the chaotic signal more diversely and thus to modulate an information signal more diversely and more adaptively.

### CROSS-REFERENCE TO RELATED APPLICATIONS

This application claims priority from Korean Patent Application No. 10-2007-xxxxxx, filed on mm dd, 2007, in the Korean Intellectual Property Office, the entire disclosure of which is hereby incorporated by reference.

### BACKGROUND OF THE INVENTION

1. Field of the Invention

Methods and apparatuses consistent with the present invention relate to a communication apparatus, and more particularly, to a communication apparatus using chaotic signals to perform communications.

2. Description of the Related Art

A technology using chaotic signals in modulating information signals is coming into existence. Such a modulating process using the chaotic signals has been increasingly used due to its advantages of reducing power consumption and simplifying a design for a transmitting end.

Therefore, several approaches and attempts to develop the modulating process using the chaotic signals have been suggested.

### SUMMARY OF THE INVENTION

Additional aspects of the present invention will be set forth in part in the description which follows and, in part, will be obvious from the description, or may be learned by practice of the present invention.

An aspect of the present invention provides a communication apparatus which is capable of adjusting a bandwidth of an oscillating signal generated from a chaotic signal to be used in the modulation, and a method for generating a signal thereof

Another aspect of the present invention provides a communication apparatus which is capable of adjusting a central frequency of an oscillating signal and a method for generating a signal thereof

According to an aspect of the present invention, there is provided a communication apparatus, comprising: a chaotic signal generator which generates a chaotic signal; an adjuster which adjusts an amplitude of the chaotic signal generated by the chaotic signal generator; and an oscillator which generates an oscillating signal having a frequency which is proportional to the amplitude of the chaotic signal adjusted by the adjuster.

The amplitude of the chaotic signal generated by the chaotic signal generator may vary with the lapse of time.

The adjuster may adjust the amplitude of the chaotic signal by a predetermined gain, and a bandwidth of the oscillating signal generated by the oscillator may be proportional to the gain.

The communication apparatus may further comprise a modulator which modulates an information signal using the oscillating signal generated by the oscillator.

According to another aspect of the present invention, there is provided a method for generating a signal, comprising: generating a chaotic signal; adjusting an amplitude of the chaotic signal; and generating an oscillating signal having a frequency which is proportional to the adjusted amplitude of the chaotic signal.

The amplitude of the chaotic signal may vary with the lapse of time.

The adjusting an amplitude comprises adjusting the amplitude of the chaotic signal by a predetermined gain, and a bandwidth of the oscillating signal generated in the generating an oscillating signal may be proportional to the gain.

The method may further comprise modulating an information signal using the oscillating signal.

According to sill another aspect of the present invention, there is provided a communication apparatus, comprising: a chaotic signal generator which generates a chaotic signal; an oscillator which generates an oscillating signal using the chaotic signal; an oscillating signal converter which converts a central frequency of the oscillating signal; a reference signal generator which generates a reference signal; and a reference signal converter which converts a frequency of the reference signal, and the oscillator may generate an oscillating signal having a central frequency which is determined based on the converted central frequency of the oscillating signal and the converted frequency of the reference signal.

The oscillating signal converter may divide the central frequency of the oscillating signal by a first division factor, and the reference signal converter divides the frequency of the reference signal by a second division factor.

The central frequency of the oscillating signal generated by the oscillator may vary with the first and the second division factors.

The communication apparatus may further comprise an amplitude adjuster which adjusts an amplitude of the chaotic signal generated by the chaotic signal generator by a predetermined gain, and applies the chaotic signal of which the amplitude is adjusted to the oscillator, and a bandwidth of the oscillating signal generated by the oscillator may be proportional to the gain since the VCO converts an oscillating frequency according to the magnitude of input voltage.

According to still another aspect of the present invention, there is provided a method for generating a signal, comprising: generating a chaotic signal; generating an oscillating signal using the chaotic signal; converting a central frequency of the oscillating signal; generating a reference signal; and converting a frequency of the reference signal. The generating an oscillating signal may comprise generating an oscillating signal having a central frequency which is determined based on the central frequency of the oscillating signal which has been converted in the converting a central frequency of the oscillating signal and based on the frequency of the reference signal which has been converted in the converting a frequency of the reference signal.

The converting a central frequency of the oscillating signal may comprise dividing the central frequency of the oscillating signal by a first division factor, and the converting a frequency of the reference signal may comprise dividing the frequency of the reference signal by a second division factor.

The central frequency of the oscillating signal generated in the generating an oscillating signal may vary with the first and the second division factors.

The method may further comprise adjusting an amplitude of the chaotic signal generated in the generating a chaotic signal by a predetermined gain, and the generating an oscillating signal may comprise generating an oscillating signal using the chaotic signal of which an amplitude is adjusted in the adjusting an amplitude of the chaotic signal, and a bandwidth of the oscillating signal may be proportional to the gain.

According to still another embodiment of the present invention, there is provided a communication apparatus, comprising a chaotic signal generator which generates a chaotic signal; an oscillator which generates an oscillating signal using the chaotic signal; a reference signal generator which generates a reference signal; and a converter which converts one of a central frequency of the oscillating signal and a frequency of the reference signal, and the oscillator may generate an oscillating signal having a central frequency which is determined based on one of the central frequency of the oscillating signal and the frequency of the reference signal that has been converted and based on the other one that has not been converted.

According to still another embodiment of the present invention, there is provided a method for generating a signal, comprising: generating a chaotic signal; generating an oscillating signal using the chaotic signal; generating a reference signal; and converting one of a central frequency of the oscillating signal and a frequency of the reference signal, and the generating an oscillating signal comprises generating an oscillating signal having a central frequency which is determined based on one of the central frequency of the oscillating signal and the frequency of the reference signal that has been converted and based on the other one that has not been converted.

### BRIEF DESCRIPTION OF THE DRAWINGS

Above and other aspects of the present invention will become apparent and more readily appreciated from the following description of the exemplary embodiments, taken in conjunction with the accompany drawings of which:

FIG. 1 is a block diagram illustrating a communication apparatus according to an exemplary embodiment of the present invention;

FIG. 2 is a block diagram illustrating a switching unit of FIG. 1;

FIG. 3 is a flowchart illustrating a process of the communication apparatus of FIG. 1 generating an oscillating signal from a chaotic signal and performing a communication using the generated oscillating signal; and

FIG. 4 is a view illustrating one example of a chaotic signal.

### DETAILED DESCRIPTION OF EXEMPLARY EMBODIMENTS

Certain exemplary embodiments of the present invention will be described in greater detail with reference to the accompanying drawings.

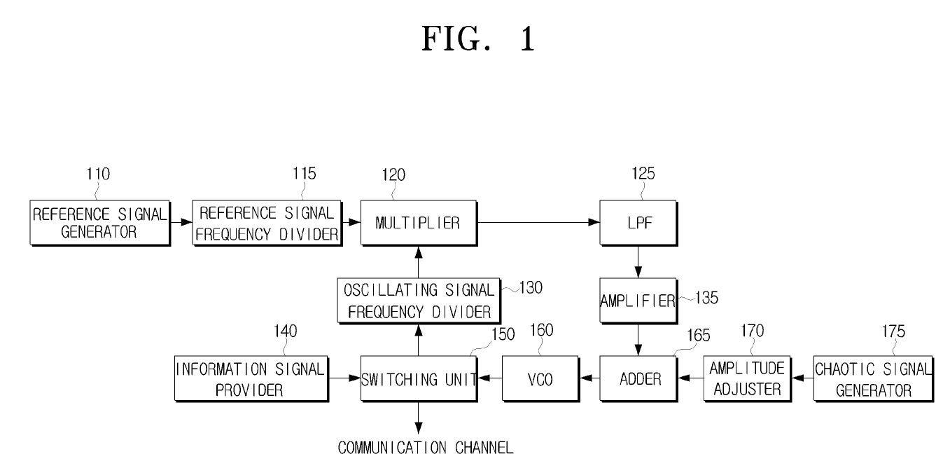

FIG. 1 is a block diagram illustrating a communication apparatus according to an exemplary embodiment of the present invention. According to an exemplary embodiment, the communication apparatus modulates an information signal using an oscillating signal generated from a chaotic signal and transmits the modulated information signal to a receiving end through a communication channel.

According to an exemplary embodiment, the communication apparatus is capable of adjusting a bandwidth and/or a central frequency of an oscillating signal generated from a chaotic signal, and of modulating an information signal using the bandwidth and/or central frequency-adjusted oscillating signal, which will be described in greater detail below.

As shown in FIG. 1, according to an exemplary embodiment of the present invention, the communication apparatus comprises a reference signal generator 110, a reference signal frequency divider 115, a multiplier 120, a low pass filter (LPF) 125, an oscillating signal frequency divider 130, an amplifier 135, an information signal provider 140, a switching unit 150, a voltage controlled oscillator (VCO) 160, an adder 165, an amplitude adjuster 170, and a chaotic signal generator 175.

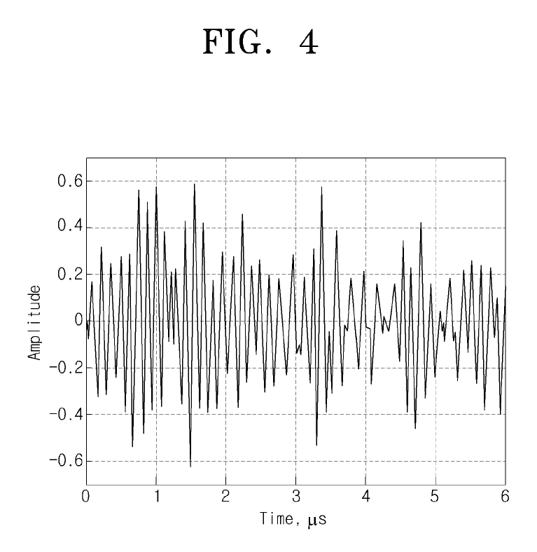

The chaotic signal generator 175 generates a chaotic signal of a low frequency band. The chaotic signal generated by the chaotic signal generator 175 is a wideband signal and its amplitude greatly varies with the lapse of time. One example of the chaotic signal generated by the chaotic signal generator 175 is shown in FIG. 4.

The amplitude adjuster 170 converts the amplitude of the chaotic signal generated by the chaotic signal generator 175. More specifically, the amplitude adjuster 170 amplifies or attenuates the chaotic signal by a predetermined gain, thereby converting the amplitude of the chaotic signal. The gain applied in the amplitude adjuster 170 is variable.

The adder 165 adds the amplitude-adjusted chaotic signal output from the amplitude adjuster 170 to an output signal of the amplifier 135, which will be described later, thereby generating a sum signal.

The VCO 160 is an oscillating element that generates an oscillating signal of which a frequency is proportional to the amplitude of the sum signal output from the adder 165, and outputs the oscillating signal.

According to the above description, 1) the sum signal output from the adder 165 consists of the chaotic signal output from the amplitude adjuster 170 and the output signal of the amplifier 135, and 2) particularly, the amplitude of the chaotic signal greatly varies with the lapse of time. Accordingly, the frequency of the oscillating signal, which is proportional to the amplitude of the chaotic signal, greatly varies with the lapse of time.

Since the amplitude of the chaotic signal greatly varies, the oscillating signal output from the VCO 160 has a wideband. Also, the VCO 160 is designed to generate a high frequency oscillating signal.

The bandwidth of the oscillating signal output from the VCO 160 equals to [(maximum amplitude of the chaotic signal)×(sensitivity of the VCO)]. Accordingly, the bandwidth of the oscillating signal output from the VCO 160 is regarded as being proportional to the maximum amplitude of the chaotic signal. That is, 1) if the amplitude of the chaotic signal is adjusted to be large by the amplitude adjuster 170, the VCO 160 outputs an oscillating signal of a wide bandwidth, and 2) if the amplitude of the chaotic signal is adjusted to be small by the amplitude adjuster 170, the VCO 160 outputs an oscillating signal of a narrow bandwidth.

The switching unit 150 modulates an information signal provided from the information signal provider 140, and transmits the modulated signal to a receiving end through a communication channel. Also, the switching unit 150 transmits the oscillating signal output from the VCO 160 to the oscillating signal frequency divider 130 to feed it back to the VCO 160.

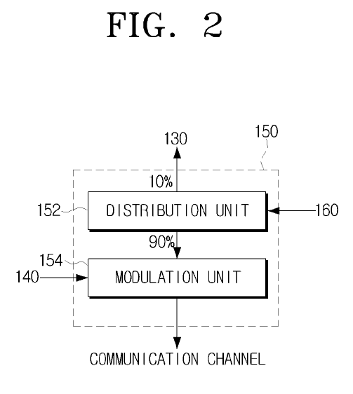

Referring to FIG. 2, the switching unit 150 comprises a distribution unit 152 and a modulation unit 154.

The distribution unit 152 distributes the oscillating signal applied from the VCO 160 such that 90% of power for the oscillating signal is transmitted to the modulation unit 154 and 10% of power is transmitted to the oscillating signal frequency divider 130.

The modulation unit 154 modulates the information signal provided from the information signal provider 140 using the oscillating signal applied from the distribution unit 152 according to an on-off keying (OOK) modulation scheme, and transmits the modulated signal to the receiving end through the communication channel.

More specifically, 1) if the information signal provided from the information signal provider 140 is “1”, the modulation unit 154 is switched on to transmit the oscillating signal generated by the VCO 160 and transmitted from the distribution unit 152 to the communication channel, and 2) if the information signal is “0”, the modulation unit 154 is switched off and do not allow the oscillating signal to be transmitted to the communication channel. That is, the modulation unit 154 is a switching element that is switched on or off under the control of the information signal.

Referring back to FIG. 1, the communication apparatus according to an exemplary embodiment of the present invention will be described.

The oscillating signal frequency divider 130 is a frequency converting element that divides a central frequency of the oscillating signal transmitted from the distribution unit 152 provided in the switching unit 150. If a division factor for the oscillating signal is “N” and if the central frequency of the oscillating signal is f_{C}, the oscillating signal frequency divider 130 lowers the central frequency of the oscillating signal to f_{C}/N. The division factor “N” for the oscillating signal is variable.

The reference signal frequency divider 115 is a frequency converting element that divides a frequency of a reference signal generated by the reference signal generator 1 10. If a division factor for the reference signal is “M” and if the frequency of the reference signal is f_{R}, the reference signal frequency divider 115 lowers the frequency of the reference signal to f_{R}/M. The division factor “M” for the reference signal is also variable.

The multiplier 120 multiplies the oscillating signal of which the central frequency is divided by the oscillating signal frequency divider 130 by the reference signal of which the frequency is divided by the reference signal frequency divider 115, thereby outputting a multiplication signal.

The LPF 125 passes therethrough a low frequency component in the multiplication signal output from the multiplier 120. The cut-off frequency of the LPF 125 may be lower than the lowest frequency of the above-described chaotic signal. Accordingly, the LPF 125 outputs a low frequency component only, which corresponds to a differential signal between the f_{C}/N and f_{R}/M, and may be approximately f_{R}/M/10.

The amplifier 135 amplifies the frequency differential signal output from the LPF 125 by a predetermined gain, and applies the amplified frequency differential signal to the above-described adder 165.

The frequency differential signal applied to the adder 165 is added to the amplitude-adjusted chaotic signal output from the above-described amplitude adjuster 170, and then applied to the VCO 160.

Since the frequency differential signal is a low frequency signal (a signal close to a direct current), the frequency differential signal determines a level of the sum signal to be applied to the VCO 160. Accordingly, the frequency differential signal serves to adjust the central frequency of the oscillating signal to be generated by the VCO 160.

More specifically, the following equation 1 is satisfied by the feedback of the frequency differential signal and can be represented as the equation 2. That is, the central frequency f_{C} of the oscillating signal generated by the VCO 160 is obtained by the equation 2.

$$\begin{matrix}\frac{{f}_{C}}{N} = \frac{{f}_{R}}{M} & [ Equation 1 ] \\ {f}_{C} = {f}_{R} \frac{N}{M} & [ Equation 2 ]\end{matrix}$$

Accordingly, the central frequency f_{C} of the oscillating signal generated by the VCO 160 can be adjusted by adjusting the division factor “N” for the oscillating signal and the division factor “M” for the reference signal besides the frequency f_{R} of the reference signal.

Also, as described above, the bandwidth of the oscillating signal generated by the VCO 160 is proportional to the amplitude of the chaotic signal adjusted by the amplitude adjuster 170. Since the amplitude of the chaotic signal is determined by the gain of the amplitude adjuster 170, the bandwidth of the oscillating signal generated by the VCO 160 is also adjusted by the gain of the amplitude adjuster 170.

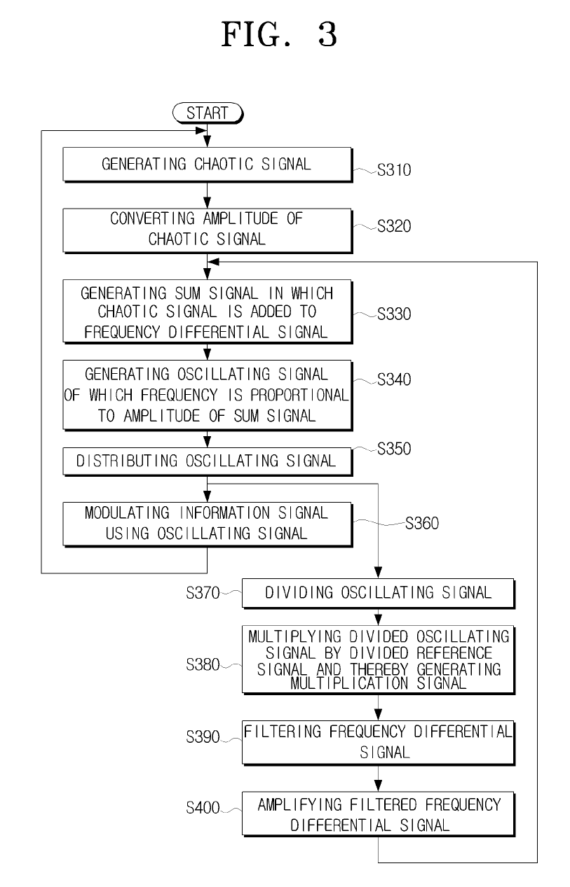

Hereinafter, a process of the communication apparatus of FIG. 1 modulating an information signal using an oscillating signal generated from a chaotic signal will be described with reference to FIG. 3.

Referring to FIG. 3, the chaotic signal generator 175 generates a chaotic signal (operation S310). The amplitude adjuster 170 converts the amplitude of the chaotic signal generated in operation S310 (operation S320). In operation S320, the amplitude adjuster 170 amplifies or attenuates the chaotic signal by a predetermined gain.

The adder 165 generates a sum signal in which the chaotic signal of which the amplitude is adjusted in operation S320 is added to a frequency differential signal which is amplified in operation S400 which will be described below (operation S330).

The VCO 160 generates an oscillating signal of which a frequency is proportional to the amplitude of the sum signal generated in operation S330 (operation S340). 1) The central frequency of the oscillating signal generated in operation S340 is proportional to the amplitude of the frequency differential signal among the components of the sum signal, and 2) the bandwidth of the oscillating signal generated in operation S340 is proportional to the amplitude of the chaotic signal among the components of the sum signal.

Since the amplitude of the frequency differential signal is adjusted by the division factor “N” for the oscillating signal and the division factor “M” for the reference signal, the central frequency of the oscillating signal is regarded as being also adjusted by the division factors “N” and “M”.

Also, since the amplitude of the chaotic signal is proportional to the gain of the amplitude adjuster 170, the bandwidth of the oscillating signal is regarded as being proportional to the gain of the amplitude adjuster 170.

The distribution unit 152 provided in the switching unit 150 distributes the oscillating signal generated in operation S340 to the modulation unit 154 and the oscillating signal frequency divider 130 (operation S350). The modulation unit 154 modulates an information signal provided from the information signal provider 140 using the oscillating signal distributed in operation S350, according to the OOK modulation scheme (operation S360). The modulated signal is transmitted to a receiving end through a communication channel.

On the other hand, the oscillating signal frequency divider 130 divides the oscillating signal distributed in operation S350 (operation S370).

The multiplier 120 multiplies the oscillating signal divided in operation S370 by the reference signal divided by the reference signal frequency divider 115, thereby generating a multiplication signal (operation S380)

Then, the LPF 125 filters a differential signal between a low frequency component of the multiplication signal output in operation S380, that is, the central frequency of the divided oscillating signal, and the frequency of the divided reference signal (operation S390). The amplifier 135 amplifies the frequency differential signal filtered in operation S390 by a predetermined gain (operation S400).

As described above, according to an exemplary embodiment of the present invention, the bandwidth and the central frequency of the oscillating signal generated from the chaotic signal is adjusted, and the information signal is modulated using the oscillating signal of which the bandwidth and the central frequency are adjusted.

Although in this embodiment the bandwidth and the central frequency of the oscillating signal are both adjusted, this is merely an example for the convenience of explanation. The present invention is applicable in the case that the bandwidth or the central frequency of the oscillating is selectively adjusted.

That is, the technical idea of the present invention can be applied in either case where only the bandwidth of the oscillating signal is adjusted or where only the central frequency of the oscillating signal is adjusted.

Also, in this embodiment, the reference signal and the oscillating signal are frequency-divided, but this is merely an example for the convenience of explanation. The technical idea of the present invention can be applied in the case that the reference signal and the oscillating signal are frequency-multiplied.

Also, in this embodiment, the reference signal and the oscillating signal are both divided, but in another embodiment, either one is divided. In that case, either the division factor “M” or the division factor “N” is 1.

As described above, according to an exemplary embodiment of the present invention, if the oscillating signal is generated from the chaotic signal to be used in the modulation, the bandwidth and/or the central frequency of the oscillating signal is adjustable. Accordingly, it is possible to transform the oscillating signal generated from the chaotic signal more diversely and thus to modulate the information signal more diversely and more adaptively.

Although a few exemplary embodiments of the present invention have been shown and described, it will be appreciated by those skilled in the art that changes may be made in these embodiments without departing from the principles and spirit of the invention, the scope of which is defined in the appended claims and their equivalents.

What is claimed is:

1. A communication apparatus, comprising:
a chaotic signal generator which generates a chaotic signal;
an adjuster which adjusts an amplitude of the chaotic signal generated by the chaotic signal generator; and
an oscillator which generates an oscillating signal having a frequency which is proportional to the amplitude of the chaotic signal adjusted by the adjuster.

2. The communication apparatus as claimed in claim 1, wherein the amplitude of the chaotic signal generated by the chaotic signal generator varies with the lapse of time.

3. The communication apparatus as claimed in claim 1, wherein the adjuster adjusts the amplitude of the chaotic signal by a predetermined gain, and a bandwidth of the oscillating signal generated by the oscillator is proportional to the gain.

4. The communication apparatus as claimed in claim 1, further comprising a modulator which modulates an information signal using the oscillating signal generated by the oscillator.

5. A method for generating a signal, comprising:
generating a chaotic signal;
adjusting an amplitude of the chaotic signal; and
generating an oscillating signal having a frequency which is proportional to the adjusted amplitude of the chaotic signal.

6. The method as claimed in claim 5, wherein the amplitude of the chaotic signal varies with the lapse of time.

7. The method as claimed in claim 5, wherein the adjusting an amplitude comprises adjusting the amplitude of the chaotic signal by a predetermined gain, and a bandwidth of the oscillating signal generated in the generating an oscillating signal is proportional to the gain.

8. The method as claimed in claim 5, further comprising modulating an information signal using the oscillating signal.

9. A communication apparatus, comprising:
a chaotic signal generator which generates a chaotic signal;
an oscillator which generates an oscillating signal using the chaotic signal;
an oscillating signal converter which converts a central frequency of the oscillating signal;
a reference signal generator which generates a reference signal; and
a reference signal converter which converts a frequency of the reference signal, and
wherein the oscillator generates an oscillating signal having a central frequency which is determined based on the converted central frequency of the oscillating signal and the converted frequency of the reference signal.

10. The communication apparatus as claimed in claim 9, wherein the oscillating signal converter divides the central frequency of the oscillating signal by a first division factor, and the reference signal converter divides the frequency of the reference signal by a second division factor.

11. The communication apparatus as claimed in claim 10, wherein the central frequency of the oscillating signal generated by the oscillator varies with the first and the second division factors.

12. The communication apparatus as claimed in claim 9, further comprising an amplitude adjuster which adjusts an amplitude of the chaotic signal generated by the chaotic signal generator by a predetermined gain, and applies the chaotic signal of which the amplitude is adjusted to the oscillator, and
wherein a bandwidth of the oscillating signal generated by the oscillator is proportional to the gain.

13. A method for generating a signal, comprising:
generating a chaotic signal;
generating an oscillating signal using the chaotic signal;
converting a central frequency of the oscillating signal;
generating a reference signal; and
converting a frequency of the reference signal, and
wherein the generating an oscillating signal comprises generating an oscillating signal having a central frequency which is determined based on the central frequency of the oscillating signal which has been converted in the converting a central frequency of the oscillating signal and based on the frequency of the reference signal which has been converted in the converting a frequency of the reference signal.

14. The method as claimed in claim 13, wherein the converting a central frequency of the oscillating signal comprises dividing the central frequency of the oscillating signal by a first division factor, and the converting a frequency of the reference signal comprises dividing the frequency of the reference signal by a second division factor.

15. The method as claimed in claim 14, wherein the central frequency of the oscillating signal generated in the generating an oscillating signal varies with the first and the second division factors.

16. The method as claimed in claim 13, further comprising adjusting an amplitude of the chaotic signal generated in the generating a chaotic signal by a predetermined gain, and wherein the generating an oscillating signal comprises generating an oscillating signal using the chaotic signal of which an amplitude is adjusted in the adjusting an amplitude of the chaotic signal, and a bandwidth of the oscillating signal is proportional to the gain

17. A communication apparatus, comprising:
a chaotic signal generator which generates a chaotic signal;
an oscillator which generates an oscillating signal using the chaotic signal;
a reference signal generator which generates a reference signal; and
a converter which converts one of a central frequency of the oscillating signal and a frequency of the reference signal, and
wherein the oscillator generates an oscillating signal having a central frequency which is determined based on one of the central frequency of the oscillating signal and the frequency of the reference signal that has been converted and based on the other one that has not been converted.

18. A method for generating a signal, comprising:
generating a chaotic signal;
generating an oscillating signal using the chaotic signal;
generating a reference signal; and
converting one of a central frequency of the oscillating signal and a frequency of the reference signal, and
wherein the generating an oscillating signal comprises generating an oscillating signal having a central frequency which is determined based on one of the central frequency of the oscillating signal and the frequency of the reference signal that has been converted and based on the other one that has not been converted.
